(19) United States
(12) Patent Application Publication
(10) Pub. No.: US 2006/0226492 A1
(43) Pub. Date: Oct. 12, 2006

(54) Semiconductor device featuring an arched structure strained semiconductor layer

(76) Inventors: Bich-Yen Nguyen, Austin, TX (US); Shawn G. Thomas, Gilbert, AZ (US); Lubomir Cergel, Geneve (CH); Mariam G. Sadaka, Austin, TX (US); Voon-Yew Thean, Austin, TX (US); Peter Wennekers, Berlin (DE); Ted R. White, Austin, TX (US); Andreas A. Wild, Grenoble (FR); Detlev Gruetzmacher, Villigen (CH); Oliver G. Schmidt, Stuttgart (DE)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 11/094,008

(22) Filed: Mar. 30, 2005

(51) Int. Cl. H01L 29/94

(52) U.S. Cl. 257/369

(57) ABSTRACT

A semiconductor device includes a mechanically strained channel, wherein the channel comprises of a single crystalline structure of a strained semiconductor layer having a non-linear geometry, the non-linear geometry including a portion of an arch shape. The semiconductor device further includes a dielectric layer, wherein a first portion of the channel is disposed overlying a point location within the dielectric layer and a second portion of the channel is disposed overlying a portion of the dielectric layer proximate to and outside of the point location. In addition, a gate is disposed proximate to the channel for controlling current flow through the channel between first and second current handling electrodes that are coupled to the channel.

### BACKGROUND

The present disclosure relates to semiconductor device structures and more particularly, to a strained semiconductor device having an arch structure and method of making the same.

### RELATED ART

In the art, there is a concept known as silicon-on-nothing which refers to having a cavity under a Si channel. However, the devices described with respect to the silicon-on-nothing concept reflect bulk CMOS type devices.

Strained Si has the potential to enhance performance of CMOS devices, that is, by increasing drive currents. However, the approaches to realizing strained Si are often complicated. Such approaches include thick graded buffer layers, condensation, wafer bonding, etc.

What is needed is an improved method and apparatus for addressing the next generation beyond silicon on nothing, that is, to be able to include strained silicon.

### BRIEF DESCRIPTION OF THE DRAWINGS

The embodiments of the present disclosure are illustrated by way of example and not limited by the accompanying figures, in which like references indicate similar elements, and in which:

FIGS. 1-7 illustrate device cross-sections at various process steps in the method of making a strained semiconductor device arch structure according to an embodiment of the present disclosure;

FIGS. 8-13 illustrate device cross-sections at various additional process steps for the fabrication of an integrated circuit device according to an embodiment of the present disclosure;

FIG. 14 is a top view of a seed layer region for use in making a strained semiconductor device arch structure according to one embodiment of the present disclosure;

FIG. 15 is a three-dimensional plan view of a strain inducing structure formed over the seed layer region of FIG. 14 according to one embodiment of the present disclosure;

FIG. 16 is a top view of an elongated seed layer region for use in making a strained semiconductor device arch structure according to another embodiment of the present disclosure;

FIG. 17 is a three-dimensional plan view of a strain inducing structure formed over the elongated seed layer region of FIG. 16 according to one embodiment of the present disclosure;

FIG. 18 is a cross-sectional view of the strained semiconductor device arch structure according to another embodiment of the present disclosure;

FIG. 19 is a cross-sectional view of the strained semiconductor device arch structure according to yet another embodiment of the present disclosure; and

FIGS. 20-24 illustrate device cross-sections at various process steps in the method of making an integrated circuit having a strained semiconductor device arch structure according to yet another embodiment of the present disclosure.

Skilled artisans appreciate that elements in the figures are illustrated for simplicity and clarity and have not necessarily been drawn to scale. For example, the dimensions of some of the elements in the figures may be exaggerated relative to other elements to help improve an understanding of the embodiments of the present disclosure.

### DETAILED DESCRIPTION

According to one embodiment, a method of forming a strained semiconductor device includes forming a local strain inducing structure of a first material and forming a single crystalline structure of a second material over the local strain inducing structure. The single crystalline structure is subject to mechanical strain by an arched surface of the strain inducing structure.

In one approach of the present disclosure, strained Si can be realized in a simple epitaxial process that allows the potential to realize a surround gate MOSFET structure, as well as, accurately tune the level of strain in the device. Additionally, the structure according to the embodiments of the present disclosure has the possibility to be integrated in a back-end process for potential 3D integration.

In one embodiment, a silicon substrate is covered with oxide and then etched to form openings (or holes) in the oxide to expose the underlying Si substrate. The openings serve as an initial template for locations where strain inducing Ge or SiGe alloy dots and subsequent strained induced MOSFET devices will be fabricated. Into the openings is deposited SiGe, where the Ge concentration can vary from 0 to 100%. In one embodiment, the SiGe layer is deposited by being grown in a selective manner, although formation of the SiGe layer is not limited to selective growth alone. For example, non-selective growth can be combined with chemical mechanical polishing (CMP) to achieve the same desired structure at this point in the process. The SiGe layer that is deposited into the holes can be amorphous, poly-crystalline or single crystalline. In a preferred embodiment, the SiGe is single crystalline.

A pure Ge or SiGe dot is then grown selectively such that the nucleation site for the Ge or SiGe dot is the SiGe filled hole (i.e., a point location). The amount of Ge in the SiGe underlying layer will determine the size of the Ge or SiGe dot that is subsequently grown. Dots can be grown in a dome shape or a hut shape and each shape may have desirable properties. Subsequently, the Ge or SiGe dot is overgrown by a thin Si layer which will eventually form the channel region of the final device. In this approach, the thin Si layer that is grown over the Ge or SiGe dot will have strain induced in the layer due to the underlying Ge or SiGe dot. It is this strain that will be utilized to fabricate a strained Si type field effect transistor (FET). Subsequent to the thin Si layer over the Ge or SiGe dot, the Ge or SiGe dot can be removed selectively, for example, using a peroxide/HF chemistry, to create a cavity below the grown Si channel region. The Si channel region maintains its convex shape in order to retain strain in the channel. CMOS fabrication can continue to form source/drain and gate on the resulting arch of strained Si. Additionally, the cavity where the Ge or SiGe dot was initially grown can be backfilled with a material so as to induce additional strain in the Si channel or with a material that can serve as a backgate to realize a double gate or surround gate MOSFET device.

Accordingly, the embodiments of the present disclosure provide an alternate path to realizing a strained Si MOSFET device as compared to traditional approaches such as graded buffer layers. Additionally, the level of strain in the Si channel can be adjusted more readily than traditional approaches so that devices with differing levels of strain can be achieved on the same wafer. This approach also identifies a path to realize a surround gate MOSFET for true volume control of the channel region. Additionally, the channel thickness is defined epitaxially, so atomically smooth top and bottom interfaces are achievable, which is a benefit over competing device structures such as FinFET which are defined by dry etching. Furthermore, the embodiments of the present disclosure can be implemented for applications of high performance CMOS or low power CMOS.

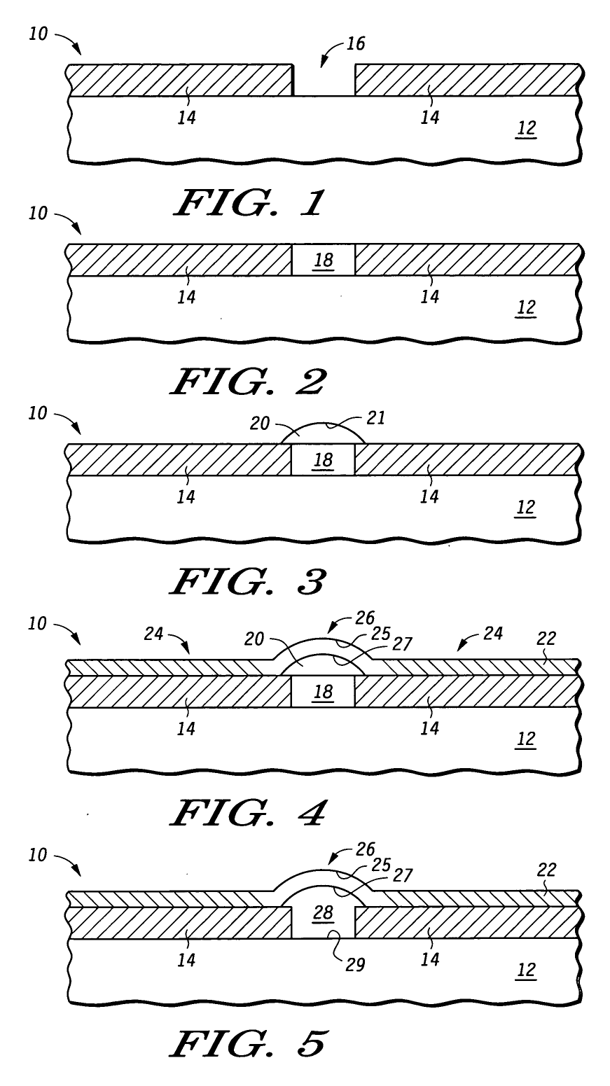

Referring now to the drawings, FIGS. 1-7 illustrate device cross-sections at various process steps in the method of making a strained semiconductor device arch structure according to one embodiment of the present disclosure. With reference now to FIG. 1, formation of a semiconductor structure 10 begins with providing a semiconductor substrate 12 and a dielectric 14 layer overlying the semiconductor substrate 12. An opening or patterned window 16 is also provided within the dielectric layer 14 at a desired location of a strained semiconductor device arch structure yet to be formed. Window 16 exposed a portion of the underlying semiconductor substrate 12.

Substrate 12 can include a bulk semiconductor substrate, a semiconductor on insulator substrate (SOI), or any other substrate suitable for a particular strained semiconductor device arch structure application. For example, substrate 12 can include a silicon substrate and dielectric layer 14 can include an oxide. Other substrate and dielectric layer combinations are also possible. For example, substrate 12 may also include a gallium arsenide (GaAs) substrate, silicon germanium (SiGe) substrate, or other suitable semiconductor substrate.

Window 16 provides a point location within dielectric layer 14 for subsequent deposition of a seed layer 18. In FIG. 2, seed layer 18 is selectively deposited inside window 16, on an exposed portion of the surface of substrate 12 within the window 16, using standard deposition techniques. Seed layer 18 can include one selected from a silicon (Si) or silicon germanium (SiGe) seed layer. For example, the silicon germanium (SiGe) seed layer can include Si₁₋ₓGeₓ. In addition, the concentration of Ge can be graded from zero percent (0%) to a few percent (%) or desired concentration. In addition, chemical mechanical polishing (CMP) can be used to smooth the top surface of seed layer 18. In one embodiment, seed layer 18 is representative of a dot when viewed from above.

In FIG. 3, a strain inducing material is selectively deposited upon an upper exposed surface of seed layer 18, such that the strain inducing material overlies slightly onto an exposed surface of dielectric layer 14 to form a strain inducing structure 20. As illustrated, a top surface 21 of the strain inducing structure 20 has a particular geometry or curvature. For example, the geometry may be that of a portion of an arched surface, a portion of a spherical shape, and a portion of a cylindrical shape. In one embodiment, the material of the strain inducing structure 20 includes silicon/silicon germanium (Si/SiGe). In one embodiment, strain inducing structure 20 is representative of a dot when viewed from above.

In FIG. 4, subsequent to forming the strain inducing structure 20, a semiconductor material 22 is grown overlying the dielectric layer 14 and the strain inducing structure 20, for example, using suitable techniques known in the art. The semiconductor material 22 is selected for use as a device active layer, as will be discussed further herein. In particular, the semiconductor material 22 is grown over the exposed surface of dielectric layer 14 in a region indicated by reference numeral 24 and over the exposed surface of the strain inducing structure 20 in a region indicated by reference numeral 26.

In one embodiment, the semiconductor material 22 includes amorphous silicon (Si). Accordingly, the semiconductor material 22 grown in the region indicated by reference numeral 24 (i.e., outside the region of the strain inducing structure 20) includes poly-silicon. The semiconductor material 22 in region 24 forms poly-silicon as a result of the layer being grown on a dielectric. Whereas, the semiconductor material 22 grown in the region indicated by reference numeral 26, overlying the strain inducing semiconductor structure 20, includes single crystal silicon.

In FIG. 5, the strain inducing structure 20 and underlying seed layer 18 are selectively removed using standard selective etch techniques after gaining access to them via a shallow trench isolation edge (not shown). Selective removal of the strain inducing structure 20 and seed layer 18 forms a corresponding void 28. In one embodiment, the strain inducing structure 20 comprises Si/SiGe or Ge and the underlying seed layer 18 comprises Ge or SiGe. In another embodiment, the semiconductor seed material and the strain-inducing structure are each comprised of at least one of group III elements and group V elements.

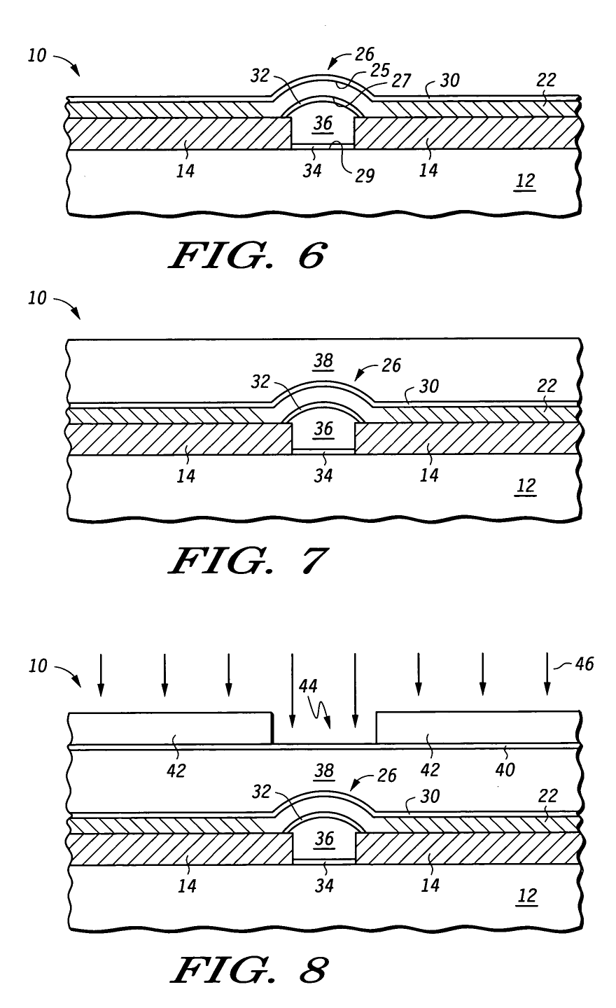

Subsequent to formation of void 28, as illustrated in FIG. 6, a dielectric layer (30,32,34) is formed overlying a top surface 25 of active layer 22, underlying an arched bottom surface 27 of active layer 22, and on a bottom surface 29 of void 28 (FIG. 5). In one embodiment, structure 10 is subjected to a control gate oxidation. Control gate oxidation forms an oxide 30 overlying the top surface 25 of active layer 22 in the region indicated by reference numeral 26, forms an oxide 32 underlying the arched bottom surface 27 of active layer 22 in the region indicated by reference numeral 26, and forms an oxide 34 at the bottom surface 29 of void 28, on an exposed portion of semiconductor substrate 12. In addition, the control gate oxidation also forms a modified opening of void 28 (FIG. 5), now indicated by reference numeral 36 (FIG. 6). Access to the void 36 is removed with completion of a shallow trench isolation filling (not shown).

Subsequent to formation of the control gate dielectric 30, the method proceeds with deposition of a control electrode material 38, as shown in FIG. 7. In one embodiment, the control electrode material 38 includes polysilicon, wherein the polysilicon is conformally deposited using standard polysilicon deposition and planarization techniques.

FIGS. 8-13 illustrate device cross-sections at various additional process steps for the fabrication of an integrated circuit device according to an embodiment of the present disclosure. Following the control gate dielectric formation, as shown in FIG. 8, a gate polysilicon patterning and implant are carried out. For example, an anti-reflective coating layer 40 is deposited overlying the control gate material 38. Anti-reflective coating layer 40 can include any suitable anti-reflective coating layer, for example, a nitride. A photo resist 42 is deposited onto the anti-reflective coating layer 40. The photo resist 42 is then patterned to form opening 44. Subsequent to forming the opening 44, a gate polysilicon implant 46 is performed according to the gate polysilicon dopant requirements of a particular strained semiconductor device application.

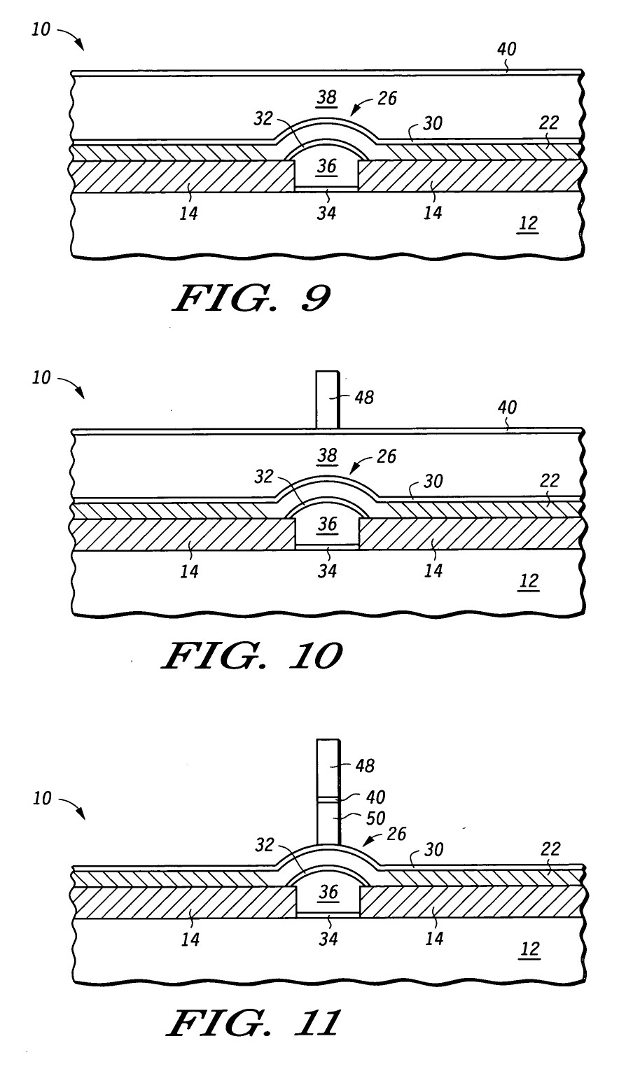

Subsequent to the gate electrode implant, the patterned photo resist 42 is removed, as shown in FIG. 9. Upon removal of the photo resist 42, another photo resist 48 is deposited and patterned, according to the particular gate electrode channel length requirements for a particular strained semiconductor device application, for example, as shown in FIG. 10. Subsequent to forming the patterned photo resist 48, the photo resist pattern 48 is transferred into the underlying anti-reflective coating layer 40 and the underlying control electrode material 38, for example, as shown in FIG. 11.

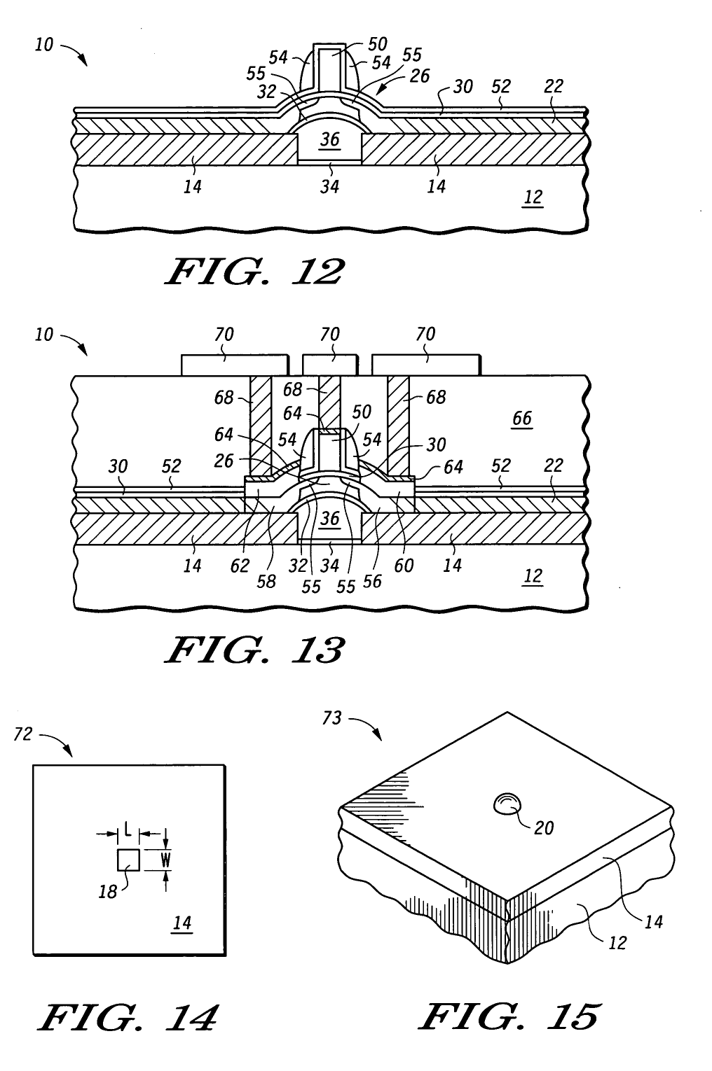

Following formation of the control electrode 50, a dielectric liner 52 is deposited, the dielectric liner for insulating, protecting, and/or passivating the corresponding underlying layers. Dielectric liner 52 includes any suitable dielectric, for example, a silicon oxide or silicon nitride. Subsequent to forming dielectric liner 52, extension implants are done for forming extension regions 53 and 55 within region 26 which corresponds to the single crystal portion of semiconductor material 22. Sidewall spacers 54 are then formed adjacent to the sidewalls of control electrode 50, with dielectric liner 52 in between the sidewall spacers and the control electrode, as shown in FIG. 12.

Various additional processing steps are carried out to form the strained semiconductor device 10 as shown in FIG. 13. Strained semiconductor device 10 includes source/drain regions (56,58), elevated source/drain regions (60,62), self-aligned silicided regions 64, and interlevel dielectric 66. Conductive vias 68 extend from a corresponding silicided contact region 64 to a top surface of the interlevel dielectric 66. Lastly, metallization 70 provides suitable contact pads for coupling to conductive vias 68.

FIG. 14 is a top view 72 of a seed layer 18 for use in making a strained semiconductor device arch structure according to one embodiment of the present disclosure. Seed layer 18 is defined by the dimensions of opening 16 (FIG. 1) in dielectric layer 14, overlying substrate 12. In the embodiment of FIG. 14, the top view 72 illustrates seed layer 18 as being defined by a length (L) and width (W), wherein the length and width are approximately equal in dimension. In other words, the point location within dielectric layer 14 as shown in FIG. 14 is defined by a length dimension and a width dimension, wherein the length dimension is approximately equal to the width dimension.

FIG. 15 is a three-dimensional plan view 73 of a strain inducing structure 20 formed over the seed layer 18 of FIG. 14 according to one embodiment of the present disclosure. As discussed earlier with respect to FIG. 3, a strain inducing material is deposited upon an upper exposed surface of seed layer 18, such that the strain inducing material overlies slightly onto an exposed surface of dielectric layer 14 to form a strain inducing structure 20. As illustrated, the top surface of the strain inducing structure 20 has a particular geometry or curvature, for example, the geometry may be that of a portion of an arched surface or a portion of a spherical shape. In the embodiment of FIG. 15, the strain inducing structure 20 resembles a dot.

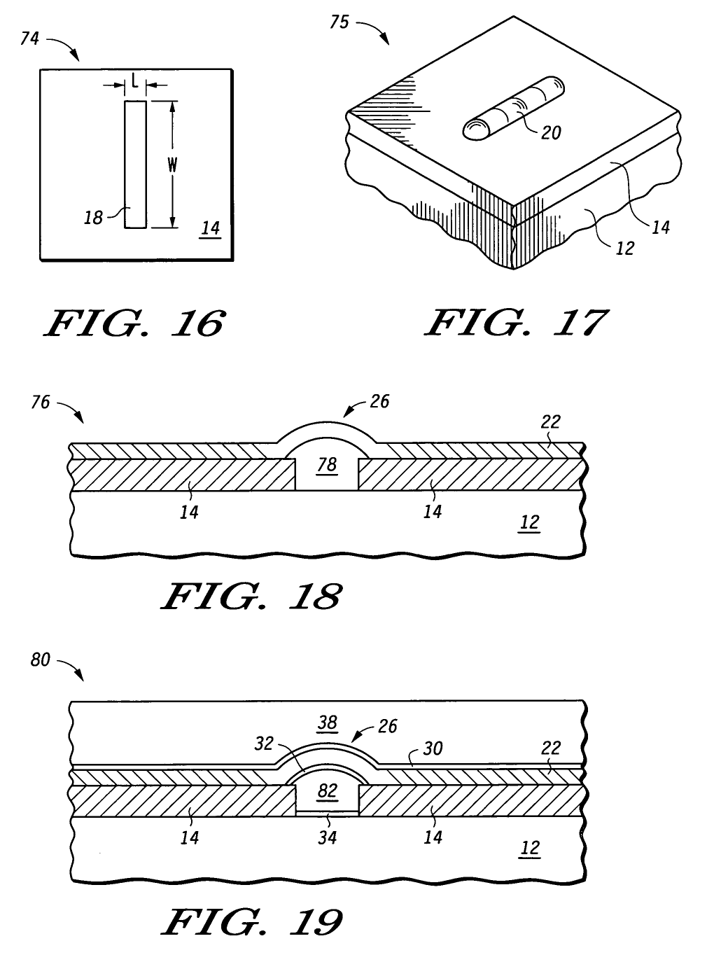

FIG. 16 is a top view 74 of an elongated seed layer 18 for use in making a strained arch structure semiconductor device according to another embodiment of the present disclosure. Seed layer 18 is defined by the dimensions of opening 16 (FIG. 1) in dielectric layer 14, overlying substrate 12. In the embodiment of FIG. 16, the top view 74 illustrates seed layer 18 as being defined by a length (L) and width (W), wherein the length dimension is smaller than the width dimension. In other words, the point location within dielectric layer 14 as shown in FIG. 16 is defined by a length dimension and a width dimension, wherein the length dimension is smaller than the width dimension.

FIG. 17 is a three-dimensional plan view 75 of a strain inducing structure 20 formed over the elongated seed layer 18 of FIG. 16 according to one embodiment of the present disclosure. As discussed earlier with respect to FIG. 3, a strain inducing material is deposited upon an upper exposed surface of seed layer 18, such that the strain inducing material overlies slightly onto an exposed surface of dielectric layer 14 to form a strain inducing structure 20. As illustrated, a top surface of the strain inducing structure 20 has a particular geometry or curvature, for example, the geometry may be that of a portion of an arched surface or a portion of a cylindrical shape. In the embodiment of FIG. 17, the strain inducing structure 20 resembles a portion of a cylinder with rounded ends.

FIG. 18 is a cross-sectional view of the strained semiconductor device arch structure 76 according to another embodiment of the present disclosure. Subsequent to selective removal of the strain inducing structure 20 and underlying seed layer 18 using standard selective etch techniques as discussed earlier herein with respect to FIG. 5, the corresponding void 28 (FIG. 5) formed by the selective removal is refilled with another material 78 (FIG. 18). The material 78 is a material selected to induce a further strain into the single crystal channel region 26 of semiconductor material layer 22. For example, material 78 can include an insulating material, such as silicon nitride, silicon oxide, or silicon oxynitride. The further strain comprises a mechanical strain. In other words, the presence of mechanical stress inducing material 78 in the void provides a greater amount of mechanical stress than was provided by the semiconductor material (20,18) that was removed (FIG. 4).

FIG. 19 is a cross-sectional view of the strained semiconductor device arch structure 80 according to yet another embodiment of the present disclosure. Subsequent to the control gate oxidation 30 and formation of a modified opening 36 as discussed earlier herein with respect to FIG. 6, the modified opening 36 (FIG. 6) is refilled with material 82. The material 82 is a material selected to induce a further strain into the single crystal channel region 26 of semiconductor material layer 22. Material 82 can be a material similar to that of material 78, as discussed with respect to FIG. 18. The further strain comprises a mechanical strain.

Furthermore, refilling the modified opening 36 with material 82 can occur with the conformal deposition of a control gate electrode material 38, as shown in FIG. 19, wherein material 82 and 38 are the same material. In one embodiment, the materials 38 and 82 include polysilicon deposited using any suitable standard polysilicon deposition techniques. The control gate electrode material 38 and 82 are selected to induce additional strain in the single crystal channel region 26 of semiconductor material layer 22. The further strain comprises a mechanical strain. Still further, materials 38 and 82 can be used to realize a surround gate MOSFET device, wherein the material 82 acts as a lower portion of the surround gate electrode and material 38 acts as an upper portion of the surround gate electrode. Similarly, a dual gate MOSFET device can be realized by making materials 38 and 82 electrically separate, wherein the material 82 acts as a lower control gate electrode and material 38 acts as an upper control gate electrode. Accordingly, the upper gate electrode structure includes a gate electrode of material 38 and a gate dielectic 30. Similarly, the lower gate electrode structure includes a gate electrode of material 82 and a gate dielectic 32.

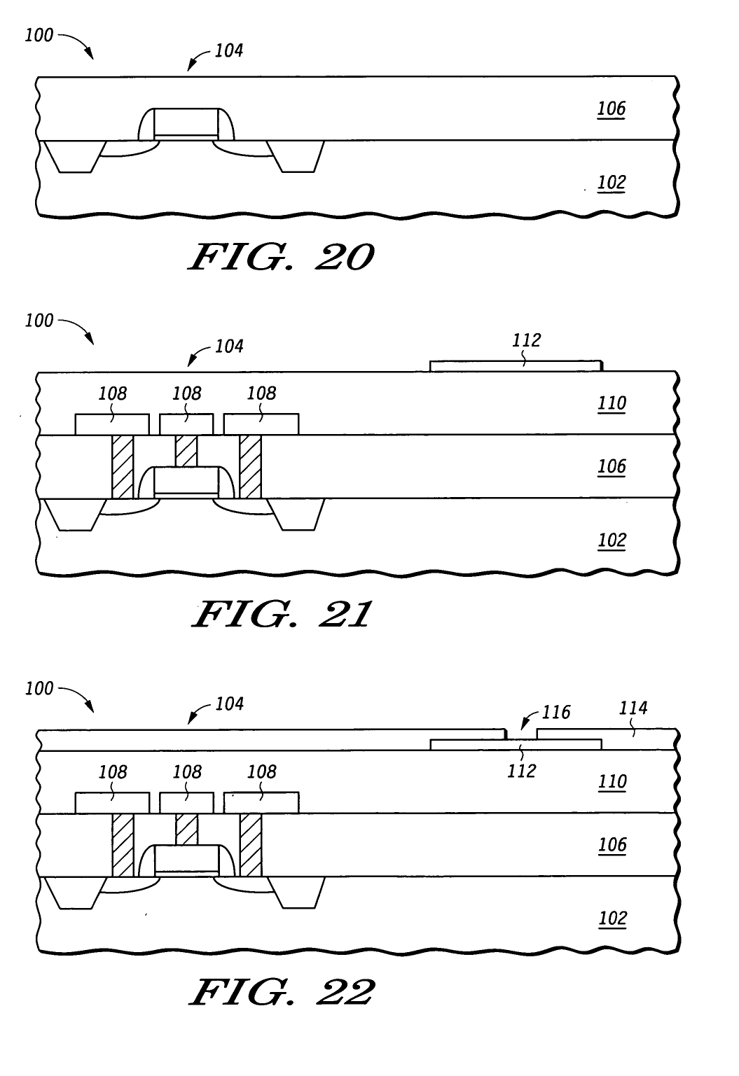

FIGS. 20-24 illustrate device cross-sections at various process steps in the method of making an integrated circuit 100 featuring a strained semiconductor device arch structure according to yet another embodiment of the present disclosure. As shown in FIG. 20, a substrate 102 is provided. A transistor device, generally indicated by reference numeral 104 is then formed using standard processing techniques. Subsequent to formation of transistor device 104, a first interlevel dielectric layer 106 is formed using standard processing techniques. The illustration in FIG. 20 is representative of a baseline CMOS/BiCMOS process.

Referring now to FIG. 21, contact vias and metalizations 108 are formed, followed by formation of a second interlevel dielectric layer 110. Following formation of the second interlevel dielectric 110, a layer of semiconductor material 112 is formed on a top surface of the second interlevel dielectric 110. The layer of semiconductor material 112 can be patterned according to the particular requirements of a strained semiconductor device arch structure being fabricated. In addition, material 112 can include an amorphous or single crystal semiconductor material. In one embodiment, material 112 includes amorphous silicon.

Referring now to FIG. 22, a layer of dielectric material 114 is deposited and an opening 116 formed in the dielectric material 114, over a portion of the semiconductor material 112. Opening 116 is similar to opening 16 as discussed earlier herein. In one embodiment, dielectric material 114 includes an oxide.

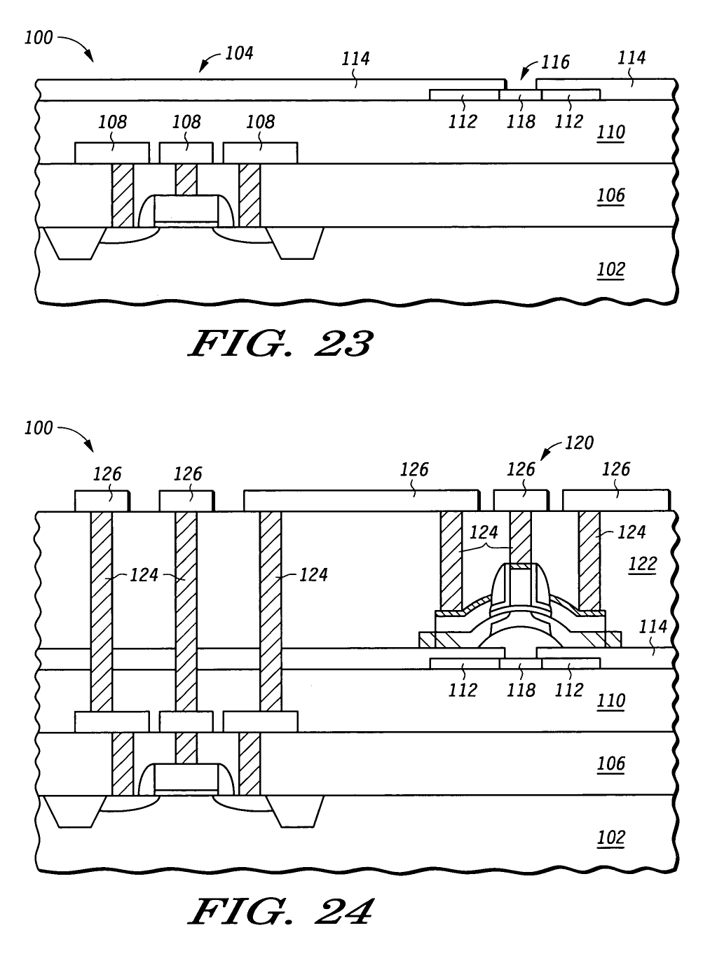

Turning now to FIG. 23, in the embodiment wherein semiconductor material 112 includes an amorphous semiconductor material, the portion of material 112 exposed by opening 116 is treated, for example, with laser re-crystallization to form a local region of single crystal semiconductor material. That is, in one embodiment, material 112 includes amorphous silicon and the laser re-crystallization forms a local region of single crystal silicon. Referring now to FIG. 24, formation of integrated circuit 100 continues with formation of a strained arch structure semiconductor device 120, using any one of the methods discussed previously herein with reference to one or more of FIGS. 2-19. Subsequent to formation of the strained arch structure semiconductor device 120, a third interlevel dielectric layer 122, as well as, contact vias 124 and metalizations 126 are formed using standard techniques.

Accordingly, in one embodiment, the forming of the local strain-inducing structure at the point location within the dielectric layer can comprise: forming an opening in the dielectric layer at a first location corresponding to the point location, wherein the opening exposes a portion of the underlying layer of semiconductor material; and forming the local strain-inducing structure (i) over the exposed portion of the underlying layer of semiconductor material or (ii) over the exposed portion of the underlying layer of semiconductor material and a portion of the dielectric layer proximate the opening in the dielectric layer. In addition, in an instance wherein the underlying layer of semiconductor material comprises a poly crystalline layer, then the method further comprises crystallizing the exposed portion of the underlying layer of semiconductor material prior to forming the local strain-inducing structure. Crystallizing the exposed portion of the underlying layer of semiconductor material can comprise the use of laser re-crystallization to form a local region of single crystal semiconductor material.

According to another embodiment, a method of forming a semiconductor device includes forming a local strain-inducing structure of a first semiconductor material at a point location within a dielectric layer. The local strain-inducing structure has a prescribed geometry with a surface disposed above a surface of the dielectric layer. A second semiconductor material is formed over the dielectric layer and the local strain inducing structure, wherein formation of a first portion of the second semiconductor material over the dielectric layer provides a poly crystalline structure of the second semiconductor material and wherein formation of a second portion of the second semiconductor material over the local strain-inducing structure provides a single crystalline structure of the second semiconductor material subject to mechanical strain by the surface of the local strain-inducing structure. The single crystalline structure serves as a strained semiconductor layer of the semiconductor device.

As discussed herein, in one embodiment, forming the local stress-inducing structure comprises forming a nucleation site at the point location and selectively growing the first semiconductor material at the nucleation site. In another embodiment, in forming a plurality of the semiconductor devices, the point location comprises a plurality of point locations that serve as an initial template for locations where local strain-inducing structures and subsequent strained semiconductor layers of the plurality of the semiconductor devices will be formed.

In yet another embodiment, the local strain-inducing structure comprises a seed layer portion of a third semiconductor material and a strain-inducing portion of the first semiconductor material. The seed layer portion is disposed (i) within an opening of the dielectric layer, or (ii) below an opening of the dielectric layer. In addition, the strain-inducing portion is disposed overlying (i) the seed layer portion and (ii) a portion of the dielectric layer proximate the opening in the dielectric layer. Furthermore, the seed layer portion comprises one of amorphous, poly-cyrstalline or single crystalline semiconductor material. Moreover, in one embodiment, the first semiconductor material can comprise Ge or SiGe, the second semiconductor material can comprise Si, and the third semiconductor material can comprise Ge or SiGe.

In a further embodiment, the seed layer portion comprises SiGe having a graded Ge concentration that varies within a range from zero to one-hundred percent (0-100%). In addition, the method further comprises selecting an amount of Ge in the SiGe seed layer portion to provide a desired size of the first semiconductor material at the point location. The size of the first semiconductor material formed over the seed layer portion is determined by the amount of Ge in the SiGe seed layer portion.

In addition, a method of forming a semiconductor device according to another embodiment includes forming a local strain inducing arch structure of a first material and forming a single crystalline region of a second material over the local strain inducing arch structure such that the single crystalline region is subject to mechanical strain by a surface of the strain inducing arch structure. In one embodiment, the first material is selected to have a first lattice constant and the second material is selected to have a second lattice constant different from the first lattice constant. As a result, in addition to the mechanical strain, the second material is further subject to lattice strain when formed over the first material. In another embodiment, the first and second materials are selected such that the first and second lattice constants have a lattice constant mismatch not substantially greater than four percent (4%).

In one embodiment, the single crystalline structure is formed so that the surface of the strain inducing structure is an arched surface. The second material is formed on the arched surface of the first material. Furthermore, the arched surface of the first material is formed to have a substantially double-curved surface having first and second orthogonal curvatures, the first and second curvatures being substantially equal and curving towards a dielectric layer or substrate underlying the semiconductor device.

In another embodiment, the strained semiconductor device is a transistor. The single crystalline structure includes a channel of the transistor. The arched surface of the first material is formed to have a substantially double-curved surface having first and second orthogonal curvatures. The first curvature is substantially greater than the second curvature and curving towards a dielectric layer or substrate underlying the semiconductor device. The second curvature is orthogonal to channel current when the device is operational. In addition, the channel is arched over the arched surface of the strain inducing structure.

In yet another embodiment, forming of the single crystalline structure includes growing the single crystalline structure to a thickness selected to facilitate fully depleted operation of the semiconductor device. The single crystalline structure is an active layer of the strained semiconductor device. In addition, a first control electrode structure can be formed over the active layer, the first control electrode structure for controlling current through the active layer when the device is operational. Still further, the method includes replacing, after removing the first semiconductor material and creating a void, the first semiconductor material with a control electrode material to provide a second control electrode structure for controlling current through the active layer when the device is operational. In one embodiment, the first and second control electrode structures are electrically coupled to provide a surround control electrode for controlling current through the active layer when the device is operational. In another embodiment, the first and second control electrode structures provide independent bias controls to independently control current through the active layer when the device is operational.

Furthermore, in yet another embodiment, a transistor includes first and second current handling electrodes and a channel coupled to each of the first and second current handling electrodes, the channel having a non-linear geometry. A gate is disposed proximate to the channel for controlling current flow through the channel between the first and second current handling electrodes. In one embodiment, the channel arches at a portion of the channel electrically between the first and second current handling electrodes. In addition, the channel has a thickness capable of fully depleted operation.

Yet still further, in another embodiment, the first and second current handling electrodes are disposed within a first plane, and the channel comprises a first portion disposed in the first plane proximate to the first current handling electrode, a second portion disposed in the first plane proximate to the second current handling electrode, and a third portion in a second plane parallel to and overlying the first plane. The gate is disposed over the channel and the channel has at least one portion with a curvature characterized by a first derivative which is positive with regard to a reference direction from the gate to the channel. In another embodiment, the transistor comprises multiple gates, with one gate above and one gate below the channel.

Further as disclosed herein, a semiconductor device includes a mechanically strained channel, wherein the channel comprises of a single crystalline structure of a strained semiconductor layer having a non-linear geometry, the non-linear geometry including a portion of an arch shape. The semiconductor device further includes a dielectric layer, wherein a first portion of the channel is disposed overlying a point location within the dielectric layer and a second portion of the channel is disposed overlying a portion of the dielectric layer proximate to and outside of the point location. In addition, a gate is disposed proximate to the channel for controlling current flow through the channel between first and second current handling electrodes that are coupled to the channel.

In the foregoing specification, the disclosure has been described with reference to various embodiments. However, one of ordinary skill in the art appreciates that various modifications and changes can be made without departing from the scope of the present embodiments as set forth in the claims below. Accordingly, the specification and figures are to be regarded in an illustrative rather than a restrictive sense, and all such modifications are intended to be included within the scope of the present embodiments. For example, the semiconductor device can include one or more of a transistor, a diode, an optical device, a light emitting diode, or a laser. An integrated circuit can also be formed using one or more of the methods according to the embodiments herein.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the term “comprises,” “comprising,” or any other variation thereof, are intended to cover a non-exclusive inclusion, such that a process, method, article, or apparatus that comprises a list of elements does not include only those elements by may include other elements not expressly listed or inherent to such process, method, article, or apparatus.

What is claimed is:

1. A semiconductor device comprising:
first and second current handling electrodes;
a channel coupled to each of the first and second current handling electrodes, the channel including a single crystalline structure of a strained semiconductor layer having a non-linear geometry, the non-linear geometry including a portion of an arch shape;
a dielectric layer, wherein a first portion of the channel is disposed overlying a point location within the dielectric layer and a second portion of the channel is disposed overlying a portion of the dielectric layer proximate to and outside of the point location; and
a gate disposed proximate to the channel for controlling current flow through the channel between the first and second current handling electrodes.

2. The semiconductor device of claim 1, wherein the portion of the arched shape comprises one of (i) a portion of a spherical shape, and (ii) a portion of a cylindrical shape with rounded ends.

3. The semiconductor device of claim 1, wherein the portion of the arched shape includes a substantially double-curved surface having first and second orthogonal curvatures, the first and second curvatures being substantially equal and curving towards the portion of the dielectric layer proximate to and outside of the point location.

4. The semiconductor device of claim 2, wherein the portion of the arched shape includes a substantially double-curved surface having first and second orthogonal curvatures, the first curvature being substantially greater than the second curvature and with both first and second curvatures curving towards the portion of the dielectric layer proximate to and outside of the point location, still further wherein the second curvature is orthogonal to a channel current when the semiconductor device is operational.

5. The semiconductor device of 1, further comprising:
a mechanical stress inducing material disposed within an opening of the dielectric layer at the point location and adjacent to an underlying surface of the channel, wherein the mechanical stress inducing material provides an increased amount of mechanical stress upon the channel than provided by an absence of the mechanical stress inducing material.

6. The semiconductor device of claim 1, further comprising:
an insulating material disposed within an opening of the dielectric layer at the point location and adjacent to an underlying surface of the channel.

7. The semiconductor device of claim 1, wherein the gate comprises a first control electrode structure formed over the strained semiconductor layer of the channel, the first control electrode structure for use in controlling current through the channel when the semiconductor device is operational.

8. The semiconductor device of claim 7, wherein the gate further comprises a second control electrode structure formed under the strained semiconductor layer of the channel within an opening of the dielectric layer at the point location, the second control electrode structure for use in controlling current through the channel when the semiconductor device is operational.

9. The semiconductor device of claim 8, further wherein the first and second control electrode structures are electrically coupled to provide a surround control electrode for use in controlling current through the channel when the semiconductor device is operational.

10. The semiconductor device of claim 8, wherein the first and second control electrode structures provide independent bias controls to independently control current through the channel when the semiconductor device is operational.

11. The semiconductor device of claim 1, wherein the semiconductor device is one of the group consisting of a transistor, a diode, an optical device, a light emitting diode, and a laser.

12. The semiconductor device of claim 1, wherein the channel is formed by a method of:
forming a local strain-inducing structure of a first semiconductor material at the point location within the dielectric layer, the local strain-inducing structure having a prescribed geometry with a surface disposed above a surface of the dielectric layer; and
forming a second semiconductor material over the dielectric layer and the local strain inducing structure, wherein formation of a first portion of the second semiconductor material over the dielectric layer provides a poly crystalline structure of the second semiconductor material and wherein formation of a second portion of the second semiconductor material over the local strain-inducing structure provides a single crystalline structure of the second semiconductor material subject to mechanical strain by the surface of the local strain-inducing structure, wherein the single crystalline structure of the second semiconductor material comprises the strained semiconductor layer for use as the channel of the semiconductor device.

13. The semiconductor device of claim 12, wherein the first semiconductor material comprises germanium (Ge) or silicon germanium (SiGe), and the second semiconductor material comprises silicon (Si).

14. The semiconductor device of claim 12, wherein further the first semiconductor material comprises a first lattice constant and the second semiconductor material comprises a second lattice constant different from the first lattice constant, wherein the single crystalline structure of the second semiconductor material is further subject to lattice strain in response to being formed over the first semiconductor material.

15. The semiconductor device of claim 1, further comprising:
a substrate, wherein the dielectric layer overlies the substrate, and wherein the point location within the dielectric layer corresponds to a portion of the substrate exposed by an opening within the dielectric layer.

16. The semiconductor device of claim 1, further comprising:
a layer of semiconductor material underlying the dielectric layer, wherein the point location within the dielectric layer corresponds to a portion of the underlying layer of semiconductor material exposed by an opening within the dielectric layer.

17. The semiconductor device of claim 16, further wherein a first portion of the underlying layer of semiconductor material proximate to and outside of the point location substantially comprises a poly crystalline layer, and wherein a second portion of the underlying layer of semiconductor material at the point location comprises a local region of single crystal material of the underlying layer of semiconductor material.

18. The semiconductor device of claim 1, wherein the point location within the dielectric layer is defined by a length dimension (L) and a width dimension (W), wherein (i) the length dimension is approximately equal to the width dimension, or (ii) the length dimension is smaller than the width dimension.

19. The semiconductor device of claim 1, wherein the channel comprises a thickness sufficient for fully depleted operation.

20. An integrated circuit comprising a plurality of semiconductor devices, wherein one or more of the semiconductor devices comprise:
first and second current handling electrodes;
a channel coupled to each of the first and second current handling electrodes, the channel including a single crystalline structure of a strained semiconductor layer having a non-linear geometry;
a dielectric layer, wherein a first portion of the channel is disposed overlying a point location within the dielectric layer and a second portion of the channel is disposed overlying a portion of the dielectric layer proximate to and outside of the point location; and
a gate disposed proximate to the channel for controlling current flow through the channel between the first and second current handling electrodes.
